(19) United States
(12) Patent Application Publication
(10) Pub. No.: US 2011/0062341 A1
(43) Pub. Date: Mar. 17, 2011

(54) SENSOR DEVICE

(76) Inventors: Utz Wever, Munchen (DE); Qinghua Zheng, Taufkirchen (DE)

(21) Appl. No.: 12/992,193

(22) PCT Filed: May 12, 2009
(86) PCT No.: PCT/EP09/55710

§ 371 Date: Nov. 11, 2010

(30) Foreign Application Priority Data
May 15, 2008 (DE) 10 2008 023 612.8

(51) Int. Cl. G01T 1/24; G01T 1/00

(52) U.S. Cl. 250/370.08; 250/336.1; 250/393

(57) ABSTRACT

A sensor device, in particular for an image recorder for recording any desired radiation, in particular electromagnetic radiation, X-ray radiation, gamma radiation or some other particle radiation has a plurality of sensor layers which are arranged above one another and each have sensor elements. In each sensor layer, coefficients of a basic function are recorded by the sensor elements which are hard-wired and each directly provide a measured value, the magnitude of which corresponds to a coefficient of the basic function which may be a wavelet basic function. The sensor device provides a recorded image in compressed form and with simultaneously little complexity and can be used in a versatile manner, in particular in an image recorder or a digital camera or, in medicine, in an X-ray machine or a tomograph. Furthermore, the sensor device can be used in a satellite for distant reconnaissance or for the purposes of astrophysics.

### CROSS-REFERENCE TO RELATED APPLICATIONS

This application is a U.S. National Stage Application of International Application No. PCT/EP2009/055710 filed May 12, 2009, which designates the United States of America, and claims priority to DE Application No. 10 2008 023 612.8 filed May 15, 2008. The contents of which are hereby incorporated by reference in their entirety.

### TECHNICAL FIELD

The invention relates to a sensor device for an image recording apparatus for recording radiation by means of sensors and to a method for recording an image.

### BACKGROUND

Sensor arrangements consisting of sensor elements are provided for example in electronic cameras. For example, an image is projected onto a CCD (Charge Coupled Device) by way of a lens system.

Due to the large number of sensor elements present on a CCD, however, an image of said kind has a very high memory space requirement. Furthermore a very high transmission capacity is required for the transmission of the image data from the camera in the case of a data processing unit.

In order to minimize the volume of data transmitted during the transmission of the image the image data is therefore often subjected to a data compression method. For example, the image data is therein subjected to what is termed a wavelet transform and subsequently compressed. Said wavelet transform of the image data does not, however, make the data memory in the camera superfluous or obsolete, since the recorded image data must first be buffered in a data memory before the wavelet transform is performed. Furthermore an additional processor unit must be provided in order to perform the wavelet transform, said processor unit increasing the technical complexity of the camera while at the same time also leading to an increased energy requirement.

U.S. Pat. No. 7,362,363 B2 therefore proposes a sensor arrangement which already at the time of recording an image generates a compressed representation of the image contents so that an additional processor unit can be dispensed with by way of the wavelet transform. For this purpose said known sensor arrangement has a plurality of sensor elements whose measured values are read with the aid of a readout means. In order to perform an overall measurement a plurality of partial measurements are performed in succession, a readout means controlling the reading of the sensor elements in such a way that in the respective partial measurements the measured values of different sensor elements in each case are added and subtracted.

However, this conventional sensor arrangement has the disadvantage that the readout means requiring to be provided in order to read out the measured values from the sensor elements has a high degree of technical complexity since the sensor or sensor arrangement must be variably wirable pixel by pixel. The manufacture of a sensor arrangement of said kind, in particular in the case of integration on a single chip, is therefore very labor-intensive and expensive. Moreover the complex readout means requires a great deal of space in the case of integration on account of its complexity.

### SUMMARY

According to various embodiments, a sensor device for recording an image can be provided which provides a compressed representation of the image contents and at the same time has the lowest possible technical complexity.

According to an embodiment, a sensor device may comprise a plurality of sensor layers arranged vertically one on top of the other, each of which consists of sensor elements, wherein coefficients of a basis function are sensorically captured in each sensor layer by means of the sensor elements, wherein the sensor elements of the sensor layers are permanently wired and each directly provide a measured value whose size corresponds to a coefficient of the basis function.

According to a further embodiment, the basis function can be a wavelet basis function. According to a further embodiment, the sensor device may provide an image recording of radiation impinging on a surface of a top sensor layer. According to a further embodiment, the sensor device may provide an image recording of electromagnetic radiation, X-ray radiation, gamma radiation or particle radiation. According to a further embodiment, a resolution frequency of a sensor layer may decrease with increasing depth of the sensor layer starting from the surface and the resolution wavelength of a sensor layer increases with increasing depth of the sensor layer starting from the surface. According to a further embodiment, the resolution frequency of a further sensor layer lying below a sensor layer can be in each case half as great as the resolution frequency of the sensor layer lying above it. According to a further embodiment, the wavelet basis function can be a Haar wavelet function, a Coiflet wavelet function, a Gabor wavelet-function, a Daubechies wavelet function, a Johnston-Barnard wavelet function, or a bioorthogonal spline wavelet function. According to a further embodiment, the sensor elements can be CCD (Charge Coupled Device) sensor elements and may have CMOS (Complementary Metal Oxide Semiconductor) sensor elements. According to a further embodiment, the sensor layers may consist of a radiation-permeable material. According to a further embodiment, the total recording time of the sensor device may correspond to the minimum exposure duration of the top sensor layer at the highest resolution frequency and at the lowest resolution wavelength. According to a further embodiment, a minimum exposure duration of a sensor layer can be inversely proportional to the recording area of a sensor element of the respective sensor layer. According to a further embodiment, the minimum exposure duration of a sensor layer may decrease exponentially with increasing depth of the sensor layer starting from the surface of the sensor device. According to a further embodiment, the recording area of a sensor element of a sensor layer may increase exponentially with increasing depth of the sensor layer starting from the surface of the sensor device. According to a further embodiment, at a resolution of 2^{N} pixels the sensor device may have N sensor layers arranged vertically one on top of the other.

According to another embodiment, an image recording apparatus may have a sensor device as described above.

According to a further embodiment of the image recording apparatus, the image recording apparatus additionally may have a signal processing device, in particular a signal compression unit, a signal filtering unit and a signal noise suppression unit. According to a further embodiment of the image recording apparatus, the coefficients of the basis function captured by sensor can be buffered in a data memory.

According to a further embodiment of the image recording apparatus, a calculation unit to which a screen is connected can be provided for the purpose of calculating an inverse wavelet transform.

According to yet another embodiment, a satellite may have a sensor device as described above, which sensor device may transmit the coefficients of the basis function captured by sensor via a radio interface to a signal processing device inside a ground station.

According to yet another embodiment, an X-ray machine may have a sensor device as described above.

According to yet another embodiment, a tomograph may have a sensor device as described above.

According to yet another embodiment, in a method for recording an image, sensor elements of a plurality of sensor layers arranged vertically one on top of the other sensorically capture coefficients of a basis function.

According to a further embodiment of the method, the basis function can be formed by means of a wavelet basis function.

According to a further embodiment of the method, residual intensities of radiation to be measured can be used in deeper sensor layers.

### BRIEF DESCRIPTION OF THE DRAWINGS

Embodiment variants of the sensor device and of the method for recording an image are described hereinbelow with reference to the attached figures, in which:

FIG. 1: shows a schematic sectional view through a sensor device according to an embodiment;

FIG. 2: shows a further sectional view to illustrate an embodiment variant of the sensor device;

FIGS. 3A, 3B: are schematic representations serving to explain the principle of operation of a sensor element used in the sensor device in comparison with a conventional sensor element. The sensor device shown measures a Haar basis;

FIG. 4: is a schematic representation of a possible embodiment variant of the sensor device serving to explain its principle of operation;

FIG. 5: shows diagrams serving to explain a special embodiment variant of the sensor device;

FIG. 6: shows a block diagram serving to illustrate a possible embodiment variant of an image recording apparatus in which the sensor device is used;

FIG. 7: shows a block diagram serving to illustrate an exemplary embodiment of a satellite in which the sensor device is used.

### DETAILED DESCRIPTION

According to various embodiments, a sensor device may have a plurality of sensor layers arranged vertically one on top of the other, each consisting of sensor elements, wherein coefficients of a basis function of a detail plane are sensorically captured in each sensor layer by means of the sensor elements, wherein the sensor elements of the sensor layers are permanently wired and in each case directly yield a measured value whose size corresponds to a coefficient of the basis function.

An advantage of the sensor manufacture according to various embodiments is that owing to the permanent wiring of the sensor elements of the different sensor layers the circuit logic of the sensor device is simplified by comparison with a conventional sensor arrangement.

In the case of the sensor device according to various embodiments the sensor elements are not variably wirable pixel by pixel, but rather the sensor elements in the sensor layers or sensor planes are permanently wired. The permanently wired sensor elements of the different sensor layers are exposed simultaneously. The incident light or, as the case may be, the radiation is used simultaneously by all the sensor elements on all the sensor layers or sensor planes.

In an embodiment variant of the sensor device the basis function is formed by means of a wavelet basis function.

In an embodiment variant of the sensor device the sensor device provides an image recording of radiation incident on a surface of a top sensor layer.

Said radiation can be any form of radiation, in particular electromagnetic radiation, X-ray radiation, gamma radiation or particle radiation.

The sensor device according to various embodiments is therefore versatile and flexible and suitable for use in the widest variety of application fields.

In an embodiment variant of the sensor device a resolution frequency of a sensor layer decreases with increasing depth of the sensor layer starting from the surface, and the resolution wavelength of a sensor layer increases with increasing depth of the sensor layer starting from the surface.

In an embodiment variant of the sensor device the resolution frequency of a further sensor layer lying under a sensor layer is in each case half as great as the resolution frequency of the sensor layer lying above.

In an embodiment variant of the sensor device the wavelet basis function used is a Haar wavelet function.

In a further embodiment variant of the sensor device the wavelet basis function is a Coiflet wavelet function.

In a possible further embodiment variant of the sensor device the wavelet basis function is a Gabor wavelet basis function.

In a further embodiment variant of the sensor device the wavelet basis function used is a Daubechies wavelet basis function.

In a further embodiment variant of the sensor device the wavelet basis function used is a Johnston-Barnard wavelet function.

In a further possible embodiment variant of the sensor device the wavelet basis function used is a bioorthogonal spline wavelet basis function.

In further possible embodiment variants further wavelet basis functions not specifically cited above can be used.

In a possible embodiment variant of the sensor device the sensor elements are CCD sensor elements.

In an alternative embodiment variant of the sensor device the sensor elements are CMOS sensor elements.

In an embodiment variant of the sensor device the sensor layers consist of a radiation-permeable material.

In an embodiment variant of the sensor device the total recording time of the sensor device corresponds to the minimum exposure duration of the top sensor layer at the highest resolution frequency and at the lowest resolution wavelength.

In an embodiment variant of the sensor device the minimum exposure duration of a sensor layer is inversely proportional to the recording area of a sensor element in the respective sensor layer.

In an embodiment variant of the sensor device the minimum exposure duration of a sensor layer decreases exponentially with increasing depth of the sensor layer starting from the surface of the sensor device.

In an embodiment variant of the sensor device the recording area of a sensor element of a sensor layer increases exponentially with increasing depth of the sensor layer starting from the surface of the sensor device.

In an embodiment variant of the sensor device the sensor device has N sensor layers arranged vertically one on top of the other at a resolution of 2^{N} pixels.

Various other embodiments also provide an image recording apparatus having a sensor device consisting of a plurality of sensor layers arranged vertically one on top of the other, each having sensor elements, wherein coefficients of a basis function are sensorically captured by sensor elements in each sensor layer and the sensor elements of the sensor layers are permanently wired and in each case directly yield a measured value whose size corresponds to a coefficient of the basis function.

In an embodiment variant of the image recording apparatus the image recording apparatus also has a signal processing device.

In a possible embodiment variant the signal processing device is a signal or data compression unit.

In a further embodiment variant of the image recording apparatus the provided signal processing unit is a signal filtering unit.

In a further possible embodiment variant the signal processing device provided in the image recording apparatus is a signal noise suppression unit.

In a possible embodiment variant of the image recording apparatus the coefficients of the basis function captured by sensor are buffered in a data memory.

In a further possible embodiment variant of the image recording apparatus a calculation unit that is connected to a screen is provided for calculating an inverse wavelet transform.

Further various embodiments provide a satellite having a sensor device which has a plurality of sensor layers arranged vertically one on top of the other, each consisting of sensor elements, wherein coefficients of a basis function are sensorically captured by the sensor elements in each sensor layer, wherein the sensor elements of the sensor layers are permanently wired and in each case directly yield a measured value whose size corresponds to a coefficient of the basis function, wherein the coefficients of the basis function captured by sensor are transmitted via a radio interface of the satellite to a signal processing device inside a ground station.

Various other embodiments provide an X-ray machine having a sensor device that has a plurality of sensor layers arranged vertically one on top of the other, each consisting of sensor elements, wherein coefficients of a basis function are sensorically captured in each sensor layer by means of the sensor elements, wherein the sensor elements of the sensor layers are permanently wired and in each case directly yield a measured value whose size corresponds to a coefficient of the basis function.

Various other embodiments provide a tomograph having a sensor device that has a plurality of sensor layers arranged vertically one on top of the other, each consisting of sensor elements, wherein coefficients of a basis function are sensorically captured in each sensor layer by means of the sensor elements, wherein the sensor elements of the sensor layers are permanently wired and in each case directly yield a measured value whose size corresponds to a coefficient of the basis function.

Various other embodiments provide a method for recording an image, wherein sensor elements of a plurality of sensor layers arranged vertically one on top of the other sensorically capture coefficients of a basis function, wherein the sensor elements are permanently wired and in each case directly yield a measured value whose size corresponds to a coefficient of the basis function.

In an embodiment variant of the method the basis function used is formed by a wavelet basis function.

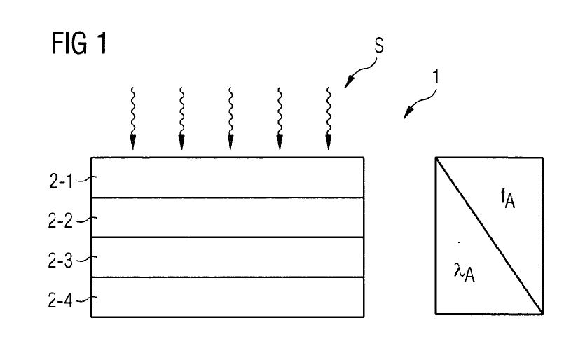

As can be seen from FIG. 1, the sensor device according to various embodiments 1 has a plurality of sensor layers, 2-1, 2-2, 2-3, 2-4, arranged vertically one on top of the other. In the example shown in FIG. 1 the sensor device 1 has N=4 sensor layers 2 arranged vertically one on top of the other. The number N of vertically arranged sensor layers can vary. In a sensor device 1 having a resolution of 2^{N} pixels, preferably N sensor layers 2 arranged one on top of the other are provided. As shown schematically in FIG. 1, radiation S impinges on the top sensor layer 2-1 of the sensor device 1. The sensor device 1 provides a recording of the incident radiation S. The radiation S can be any form of radiation, in particular electromagnetic radiation, X-ray radiation, gamma radiation or particle radiation. Sensor elements that sensorically capture coefficients c of a basis function BF are provided distributed over the surface in each sensor layer 2-i. In this arrangement the sensor elements of the sensor layers 2 are permanently wired and in each case directly provide a measured value whose size corresponds to a coefficient c of the basis function BF. A wavelet basis function W-BF is preferably used as the basis function BF. The sensor device 1 provides an image recording of the radiation S impinging onto the surface of the top sensor layer 2-1.

As indicated schematically in FIG. 1, a resolution frequency f_{A} of a sensor layer 2 preferably decreases in this case with increasing depth of the sensor layer starting from the surface onto which the radiation S impinges. At the same time the resolution wavelength λ_{A} of a sensor layer 2 increases with increasing depth of the sensor layer starting from the surface onto which the radiation S impinges. In the exemplary embodiment shown in FIG. 1 the top sensor layer 2-1 therefore has the highest resolution frequency f_{A} and at the same time the lowest resolution wavelength λ_{A}. Conversely the bottom sensor layer 2-4 has the lowest resolution frequency f_{A} and the highest resolution wavelength λ_{A}.

In a possible embodiment variant of the sensor device 1 the resolution frequency f_{A} of a further sensor layer 2-(i+1) lying under a sensor layer 2-i is in each case half as great as the resolution frequency of the sensor layer 2-i lying above it.

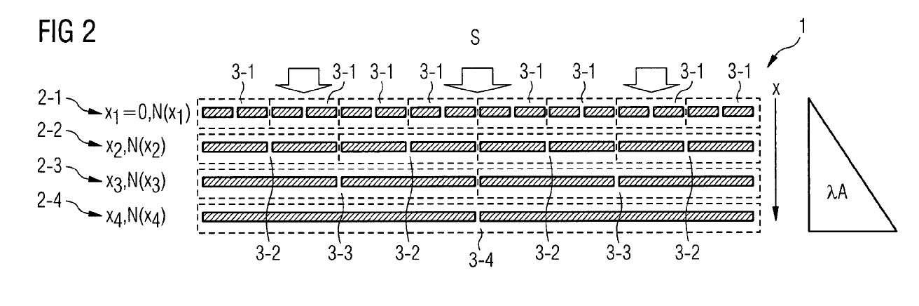

FIG. 2 also shows a schematic sectional view through the sensor device 1 depicted in FIG. 1. As shown in FIG. 2, a plurality of sensor elements 3-i are disposed in each sensor layer 2-i. In the example represented schematically in FIG. 2 eight sensor elements 3-1 are contained in the top sensor layer 2-1, four sensor elements 3-2 in the second sensor layer 2-2, three sensor elements 3-3 in the third sensor layer 2-3, and a single sensor element 3-4 in the bottom sensor layer 2-4. As can be seen from FIG. 2, the size or, as the case may be, recording surface area of the sensor elements 3-i increases with increasing depth of the sensor layer. In a possible embodiment variant of the sensor device 1 the recording surface area of a sensor element 3-i doubles in each further sensor layer starting from the top sensor layer 2-1 down to the bottom sensor layer 2-N.

The sensor elements 3-i can be CMOS (Complementary Metal Oxide Semiconductor) sensor elements. In an alternative embodiment variant the sensor elements 3-i are CCD (Charge Coupled Device) sensor elements.

The sensor layers 2-i of the sensor device 1 consist of a radiation-permeable material, the material being dependent on a particular type of the radiation S that is to be recorded. The absorption of the radiation S is described by means of an exponential law, the Lambert-Beer law:

$$\frac{d N}{d x} = - μ N ( x ) ⇒ N ( x ) = N ( 0 ) {e}^{- μ x}$$

The exposure duration is inversely proportional to the recording area and decreases exponentially with the refinement level or, as the case may be, depth of the sensor layer 2-i starting from the surface.

In an embodiment variant of the sensor device 1 said absorption law is used for the purpose of correctly exposing the sensor plane or sensor layers through the suitable arrangement depth of the wired sensor layers 2-i, the installation depth x of the sensor layers 2-i and the photon energy for the exposure being calculated for the purpose of dimensioning the sensor device 1.

In a possible embodiment variant of the sensor device 1 the installation depth in a sensor layer 2-i is yielded according to the Lambert law M(x)=N(0)e^{-μx}, where μ is dependent on the material and the frequency of the radiation to be measured. If the normalized exposure is 1, the surface x1=0 is exposed to the intensity N(x1)=½. The installation depth x2 for the second sensor layer 2-2 is yielded as a function of the material constant μ corresponding to ¼ of the intensity of the light:

N(x2)=¼=½e^{μx2},

i.e. the installation depth for the second sensor layer 2-2 is yielded as:

$${x}_{2} = - \frac{1}{μ} ln ( \frac{1}{2} ) .$$

The installation depth x3 for the next sensor layer 2-3 is yielded such that, as a function of the material constant μ, at least ⅛ of the light intensity or radiation intensity still arrives there:

N(x3)=⅛=½e^{-μx3}.

Thus, the installation depth x3 of the third sensor layer 2-3 is yielded as follows:

$${x}_{3} = - \frac{1}{μ} ln ( \frac{1}{4} ) .$$

Analogously, the installation depth of the fourth sensor layer 2-4 is yielded as:

$$N ( x 4 ) = 1 / 16 = \frac{1}{2} {e}^{- μ x 4} . \\ Thus , {x}_{4} = - \frac{1}{μ} ln ( \frac{1}{8} ) .$$

The installation depth x₄ of the lowest sensor layer 2-4 yields the thickness of the sensor device 1 according to various embodiments. The thickness of the sensor device 1 according to various embodiments is therefore dependent on the constant μ of the material used for the sensor elements 3, which for its part is determined by the radiation S that is to be captured.

In the sensor device 1 according to various embodiments, as shown in FIG. 2, a plurality of sequentially layered radiation-permeable sensor elements of different sensor layers 2 are exposed to the radiation S originating from the same radiation source. The intensity of the radiation S in this case decreases exponentially with a penetration depth x of the radiation S into the sensor device 1. The sensor elements 3-i of the different sensor layers 2-i are dimensioned such that with increasing penetration depth they require exponentially less radiation, i.e. the recording area of the sensor elements 3 increases with increasing layer depth xᵢ of the respective sensor layer 2-i, as shown schematically in FIG. 2.

The sensor elements 3-i are radiolucent and connected one after the other in series. The requisite minimum overall recording time is in this case determined by the first sensor layer 2-i or sensor plane. The total recording time of the sensor device 1 corresponds to the minimum exposure duration of the top sensor layer 2-1 having the highest resolution frequency f_{A} and the lowest resolution wavelength λ_{A}. Owing to the fact that the sequentially connected linear sensor elements 3-i are exposed simultaneously, half the exposure is saved in the case of the sensor device 1 according to various embodiments, since the incident radiation is used for all the sensor layers 2-i. Owing to a differential measurement the finest sensor plane or, as the case may be, the top sensor layer 2-1 requires half the conventional exposure. The absorbed residual radiation can be used by additional exposure of the deeper-lying sensor planes or sensor layers. In this case the full intensity and hence the same image quality is added as follows:

$${\sum }_{i = 1}^{∞} {2}^{- i} = 1 ,$$

where i is the sensor layer 2-i.

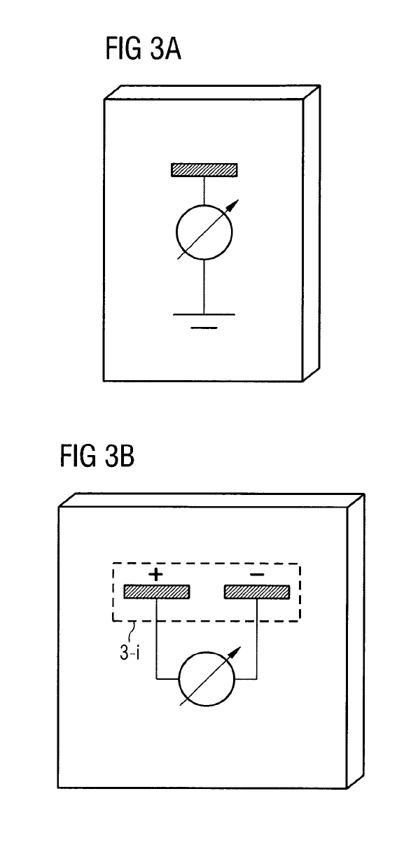

FIGS. 3A, 3B schematically show the exposure measurement on a sensor element 3-i of the sensor device 1 according to various embodiments (FIG. 3B) compared to the exposure measurement by means of a conventional sensor element (FIG. 3A). A conventional exposure measurement takes twice as long as a differential measurement for the same pixel size, because the differential measurement uses two pixels for the exposure measurement. The differential measurement can be performed simultaneously in each sensor layer 2-i.

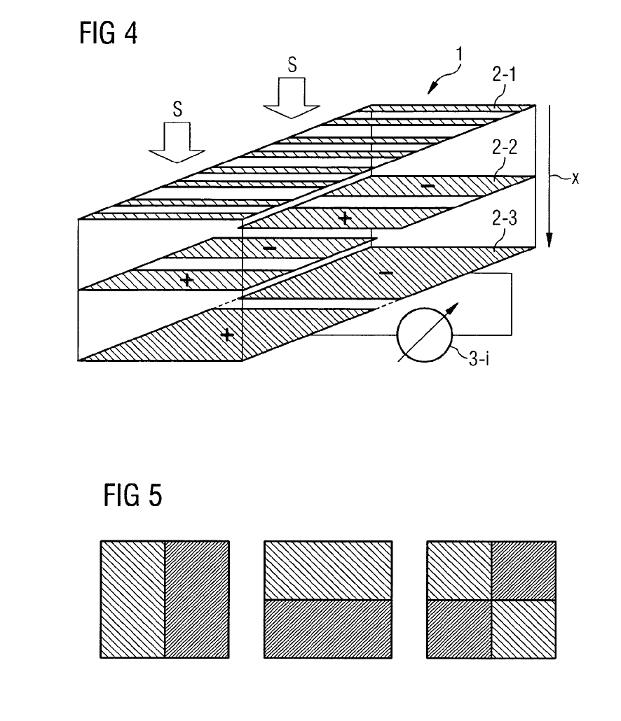

FIG. 4 schematically shows the structure of a sensor device 1 according to various embodiments having three sensor layers 2-1, 2-2, 2-3. Radiation S, for example light radiation or particle radiation, impinges onto the surface of the top sensor layer 2-1. As can be seen, the recording area of the single sensor element within the bottom sensor layer 2-3 is considerably larger than the recording area of the sensor elements contained in the top sensor layer 2-1.

FIG. 5 shows a diagram intended to illustrate a possible embodiment variant of the sensor device 1. In this embodiment variant a plurality of sublayers are for their part provided in each sensor layer 2-i. For example, as shown in FIG. 5, three sublayers can be provided. In this exemplary embodiment three differential measurements are performed per sensor layer or sensor plane 2-i, each in a quarter of the exposure time. Accordingly the intensities of the recorded layers add up to 1:

$${3 \sum }_{i = 1}^{∞} {4}^{- i} = 1.$$

In the case of the sensor device 1, as shown schematically in the exemplary embodiments according to FIGS. 1 to 5, coefficients c of a basis function BF are sensorically captured by means of the sensor elements 3-i of each sensor layer 2-i. In an embodiment variant said basis function BF is what is termed a wavelet basis function. In contrast to sine and cosine functions that are used in, for example, the Fourier transform, wavelet functions exhibit locality not only in the frequency spectrum, but also in the time domain or, as the case may be, in the spatial domain, i.e. they possess little scatter both in the frequency spectrum and in the time domain or spatial domain. As a result of the transformation the image data is brought into a form of representation which offers advantages in subsequent operations or signal processing steps. The direct generation of wavelet coefficients by the sensor device 1 according to various embodiments offers the advantage that no independent processing unit or transformation unit needs to be provided for performing wavelet transforms of said kind. In contrast to periodic basis functions, as used in the Fourier transform, local basis functions, such as wavelet basis functions, which occupy finite intervals both in the time (spatial) and in the frequency domain, are suitable in particular for signal discontinuities. Owing to the locality of the wavelet basis functions, therefore, particularly steep edges of functions can also be optimally represented. The basis functions include what are termed scaling functions and wavelet basis functions. Said functions have the fundamental characteristics of orthogonality, i.e. the vectors of the functions are at right angles to one another, thereby enabling a transformation and an identical reconstruction. Owing to their finite extension the basis functions enable image data to be analyzed without window effects.

In an embodiment variant of the sensor device 1 the permanently wired sensor elements 3-i of the sensor layers 2-i in each case form a measured value whose size corresponds to a coefficient c of the basis function BF, in particular a wavelet basis function.

In a possible embodiment variant of the sensor device 1 the wavelet basis function is a Haar wavelet basis function.

In alternative embodiment variants other wavelet basis functions can also be used, for example a Coiflet wavelet basis function, a Gabor wavelet basis function, a Daubechies wavelet basis function, a Johnston-Barnard wavelet basis function or a biorthogonal spline wavelet basis function.

At a resolution of 2^{N} pixels the sensor device 1 according to various embodiments has N sensor layers 2-i vertically arranged one on top of the other. For example, at a resolution of 1024=10¹° pixels the sensor device 1 has a linear arrangement of 10 sensor layers 2-i layered one on top of the other.

In a possible embodiment variant of the sensor device 1 a plurality of pixels in a sensor layer 2-i are linked with or, as the case may be, multiplied by prefactors. In this case the prefactors are yielded from the construction of the wavelets. Sensor layers or sensor planes can be economized by means of higher wavelets.

The material of the sensor elements 3 and the particle energy are chosen such that the absorption coefficient has a suitable value and the associated layer depth of the individual sensors can be constructed.

In a possible embodiment variant sensors 3 can consist of individual groups. In the sensor device 1 according to various embodiments larger surface areas or recording areas of the lower-lying sensor elements of the underlying sensor layers are used in order to scatter the beams that are caused by higher-lying sensors or sensor elements in above-lying sensor layers 2.

In an embodiment variant of the sensor device 1 a Haar wavelet basis function is used as the basis function BF.

The Haar wavelet basis function is defined by:

$$ψ ( x ) = \{ \begin{matrix}1 & for 0 \leq x < \frac{1}{2} \\ - 1 & for ( \frac{1}{2} \leq x < 1 ) \\ 0 & otherwise\end{matrix}$$

The wavelet basis is then defined as

Ψ_{m,n}(x)=2^{-m}Ψ(2^{-m}x−n), m=1, . . . , L, n=0, . . . , 2^{L-m}−1,

where n resolves the space, and m specifies the spatial frequency or the level of detailing.

Functions can be represented as a wavelet series:

$$f = {f}^{L + 1} + {\sum }_{m = L}^{1} {\sum }_{l = 0}^{{2}^{L - {m}_{- 1}}} {c}_{m , l} {ψ}_{m , l} ( x )$$

The function f (the image to be recorded) is given by 2^{L} discrete points:

f={f}ᵢ, i=0, . . . , 2^{L}−1

There are L layers. The wavelet coefficients of a detail plane are measured in a layer m with m: 1≦m≦L:

c_{m,l}, l=0, . . . , 2^{L-m}−1

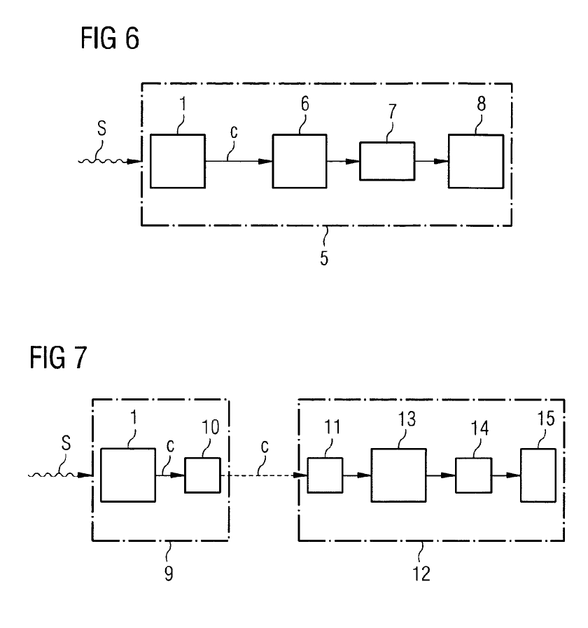

FIG. 6 shows a block diagram of a possible embodiment variant of an image recording apparatus 5 that includes a sensor device 1. The sensor device 1 directly provides measured values whose size or height in each case corresponds to a coefficient c of the implemented basis function BF. Said coefficients c are output to a signal processing device 6 inside the image recording apparatus 5. In a possible embodiment variant the generated coefficients c are initially stored temporarily in a buffer memory. The signal processing device 6 can be a signal compression unit, a signal filtering unit or even a signal noise suppression unit. The processed coefficients c can then be supplied to a calculation unit 7 which performs an inverse transform, in particular an inverse wavelet transform. The transformation unit 7 provides an image, displayable on the screen 8, of the radiation S recorded by the sensor device 1. The image recording apparatus 5, as shown in FIG. 6, can be a camera for example. Furthermore the image recording apparatus 5 can also be an X-ray machine for recording X-ray radiation S. A further exemplary application of the apparatus 5 shown in FIG. 6 is a tomograph.

FIG. 7 shows a further exemplary application of the sensor device 1. In this exemplary application the sensor device 1 is provided in a satellite 9 and provides coefficients c of a basis function BF to a transmitter device 10 of the satellite 9 which transmits the coefficients c via a radio interface to a receiver unit 11 inside a ground station 12. A signal processing device 13 can be provided in the ground station 12 for the purpose of processing the transmitted coefficients c. Said processed coefficients can be subjected to an inverse transform by means of a calculation unit 14 and displayed on a screen 15 of the ground station 12.

By means of a layerwise arrangement of sensor groups or sensor elements 3 the sensor device 1 according to various embodiments successively utilizes a residual radiation.

The simultaneous exposure of the sensor groups offers in particular the following advantages:

At the same radiation intensity and resolution the sensor groups are exposed for a shorter exposure time.

With the same exposure time and resolution the simultaneous exposure of the sensor groups leads to a lower requisite radiation intensity of the radiation S.

At the same radiation intensity and exposure the simultaneous exposure of the sensor groups leads to a higher resolution.

The sensor device 1 according to various embodiments additionally offers the advantage that a maximum resolution can always be achieved through a sufficiently long recording or exposure time.

Above all, the sensor device 1 according to various embodiments offers the advantage that the required information or, as the case may be, the image data is available or generated directly in compact form and consequently a necessary memory space requirement is minimized.

The memory device according to various embodiments additionally offers a high degree of flexibility in terms of adaptation for different fields of application.

In a possible embodiment variant known noise frequencies of noise signal sources can be suppressed directly during the recording of the image by selectively omitting or not implementing sensor planes or sensor layers 2-i. The measurement time or exposure time can be optimized during the exposure independently of the location. Consequently the total measurement time of the sensor device 1 does not have to be predefined a priori.

The sensor device 1 according to various embodiments also offers a high recording dynamic, since differences in intensities are measured, and not absolute values.

The sensor device 1 according to various embodiments is suitable for the most diverse applications, for example for generating X-ray photographs, for long-range reconnaissance applications and applications in astrophysics, as well as for digital photography.

The exemplary embodiments presented are suitable for performing intensity measurements of the incident radiation. If a color measurement is desired, in a possible embodiment variant all the images can be recorded for the three primary colors or a color dispersion is performed in some other way.

In a possible embodiment variant the same basis function BF is used for each color. In an alternative embodiment variant a different basis function, in particular also a different wavelet basis function, can also be used for each color.

What is claimed is:

1. A sensor device comprising
a plurality of sensor layers arranged vertically one on top of the other, each of which consists of sensor elements,
wherein coefficients of a basis function are sensorically captured in each sensor layer by means of the sensor elements,
wherein the sensor elements of the sensor layers are permanently wired and each directly provide a measured value whose size corresponds to a coefficient of the basis function.

2. The sensor device according to claim 1,
wherein the basis function is a wavelet basis function.

3. The sensor device according to claim 1,
wherein the sensor device provides an image recording of radiation impinging on a surface of a top sensor layer.

4. The sensor device according to claim 3,
wherein the sensor device provides an image recording of electromagnetic radiation, X-ray radiation, gamma radiation or particle radiation.

5. The sensor device according to claim 4,
wherein a resolution frequency of a sensor layer decreases with increasing depth of the sensor layer starting from the surface and the resolution wavelength of a sensor layer increases with increasing depth of the sensor layer starting from the surface.

6. The sensor device according to claim 5,
wherein the resolution frequency of a further sensor layer lying below a sensor layer is in each case half as great as the resolution frequency of the sensor layer lying above it.

7. The sensor device according to claim 2,
wherein the wavelet basis function is
a Haar wavelet function,
a Coiflet wavelet function,
a Gabor wavelet-function,
a Daubechies wavelet function,
a Johnston-Barnard wavelet function, or
a bioorthogonal spline wavelet function.

8. The sensor device according to claim 1,
wherein the sensor elements are Charge Coupled Device (CCD) sensor elements and
have Complementary Metal Oxide Semiconductor (CMOS) sensor elements.

9. The sensor device according to claim 1,
wherein the sensor layers consist of a radiation-permeable material.

10. The sensor device according to claim 1,
wherein the total recording time of the sensor device corresponds to the minimum exposure duration of the top sensor layer at the highest resolution frequency and at the lowest resolution wavelength.

11. The sensor device according to claim 10,
wherein a minimum exposure duration of a sensor layer is inversely proportional to the recording area of a sensor element of the respective sensor layer.

12. The sensor device according to claim 11,
wherein the minimum exposure duration of a sensor layer decreases exponentially with increasing depth of the sensor layer starting from the surface of the sensor device.

13. The sensor device according to claim 12,
wherein the recording area of a sensor element of a sensor layer increases exponentially with increasing depth of the sensor layer starting from the surface of the sensor device.

14. The sensor device according to claim 1,
wherein at a resolution of 2^{N} pixels the sensor device has N sensor layers arranged vertically one on top of the other.

15. An image recording apparatus having a sensor device according to claim 1.

16. The image recording apparatus according to claim 15,
wherein the image recording apparatus further comprises a signal processing device optionally with a signal compression unit, a signal filtering unit and a signal noise suppression unit.

17. The image recording apparatus according to claim 15,
wherein the coefficients of the basis function captured by sensor are buffered in a data memory.

18. The image recording apparatus according to claim 15,
wherein a calculation unit to which a screen is connected is provided for the purpose of calculating an inverse wavelet transform.

19. A satellite having a sensor device according to claim 1, which sensor device transmits the coefficients of the basis function captured by sensor via a radio interface to a signal processing device inside a ground station.

20. An X-ray machine having a sensor device according to claim 1.

21. A tomograph having a sensor device according to claim 1.

22. A method for recording an image,
comprising: arranging sensor elements of a plurality of sensor layers vertically one on top of the other and sensorically capturing coefficients of a basis function by said sensor elements.

23. The method according to claim 22,
wherein the basis function is formed by means of a wavelet basis function.

24. The method according to claim 22,
wherein residual intensities of radiation to be measured are used in deeper sensor layers.
